(19) United States
(12) Patent Application Publication
(10) Pub. No.: US 2026/0202491 A1
(43) Pub. Date: Jul. 16, 2026

(54) SYSTEM AND METHODS FOR BATTERY ISOLATION FAULT DIAGNOSIS

(71) Applicant: Proterra Powered, LLC, Burlingame, CA (US)

(72) Inventor: THOMAS BLAZAK, Burlingame, CA (US)

(73) Assignee: Proterra Powered, LLC, Burlingame, CA (US)

(21) Appl. No.: 19/020,883

(22) Filed: Jan. 14, 2025

(51) Int. Cl. G01R 31/52; G01R 31/3842; G01R 31/396; H01M 10/42; H01M 10/48

(52) U.S. Cl. CPC G01R 31/52; G01R 31/3842; G01R 31/396; H01M 10/425; H01M 10/482; H01M 2010/4271; H01M 2220/20

(57) ABSTRACT

A battery system may include a plurality of high-voltage (HV) battery packs, each HV battery pack including a plurality of battery cells enclosed within a housing. A battery management system (BMS) can be electrically connected to each of the HV battery packs configured to control the plurality of HV battery packs. The BMS can include a controller configured to identify an isolation breakdown based at least on whether a low resistance connection exists between a portion of a series connection of the plurality of battery cells and a chassis ground of the electric vehicle; and determine an electrical location of a fault in the plurality of HV battery packs based at least on a battery pack positive voltage and a battery pack negative voltage.

### TECHNICAL FIELD

Embodiments of this disclosure relate to battery systems and related operations.

### BACKGROUND

High-voltage (HV) batteries are used to recharge and sustain low voltage operations while a vehicle is in operation. Battery systems can experience issues measuring isolation resistance of the high voltage contained within. Current approaches related to measuring isolation resistance of a battery, however, only provide indication of the fault and do not provide any indication of where the fault physically exists within the HV battery. Embodiments of the current disclosure may address these limitations and/or other problems in the art.

### SUMMARY

Embodiments of the present disclosure relate to, among other things, battery systems for electric vehicles. Each of the embodiments disclosed herein may include one or more of the features described in connection with any of the other disclosed embodiments.

In one embodiment, a battery system may include a battery system of an electric vehicle. A plurality of high-voltage (HV) battery packs where each HV battery pack has a plurality of battery cells enclosed within a housing. A battery management system (BMS) can be electrically connected to each of the HV battery packs and is configured to control the plurality of HV battery packs. The BMS can include a controller configured to identify an isolation breakdown based at least on whether a low resistance connection exists between a portion of a series connection of the plurality of battery cells and a chassis ground of the electric vehicle; and determine an electrical location of a fault in the plurality of HV battery packs based at least on a battery pack positive voltage and/or a battery pack negative voltage.

In some aspects, the controller of the BMS is configured to determine a physical location of the fault based at least on a number of the plurality of battery cells less the battery pack positive voltage divided by an average cell voltage.

In some aspects, the controller of the BMS is configured to determine a physical location of the fault based at least on voltage measurements of each cell voltage in a series string and positive and/or negative pack voltage.

In some aspects, the battery pack positive voltage is a measurement of a positive-most portion of a series connection of the plurality of battery cells with respect to the chassis ground.

In some aspects, the battery negative voltage is a measurement of a negative-most portion of a series connection of the plurality of battery cells with respect to the chassis ground.

In some aspects, the determining the electrical location of the fault in the plurality of HV battery packs is based at least on cell voltages.

In some aspects, the battery pack positive voltage is a measurement of a most positive portion of a series connection of the plurality of battery cells with respect to a chassis ground. The battery pack negative voltage is a measurement of a most negative portion of a series connection of the plurality of battery cells with respect to a chassis ground. A sum of a magnitude of the battery pack positive voltage and the battery pack negative voltage values equals a total pack voltage.

In some aspects, the isolation resistance is calculated by connecting a known resistance between either the battery pack positive voltage and a chassis ground or the battery pack negative voltage and the chassis ground and calculating a change in voltage measurement.

In another embodiment, a method is disclosed for determining an electrical location of a fault in a plurality of HV battery packs of a battery system of an electric vehicle. The method can include identifying an isolation breakdown based at least on whether a low resistance connection exists between a portion of a series connection of a plurality of battery cells of the plurality of HV battery packs and a chassis ground of the electric vehicle. The method can include determining an electrical location of a fault in the plurality of HV battery packs based at least on a battery pack positive voltage and a battery pack negative voltage.

In some aspects, the method can include determining a physical location of the fault based at least on a number of the plurality of battery cells less the battery pack positive voltage divided by an average cell voltage.

In some aspects, the method can include determining a physical location of the fault based at least on voltage measurements of each cell voltage in a series string and positive and/or negative pack voltage.

In some aspects, the determining the electrical location of the fault in the plurality of HV battery packs is based at least on all cell voltages.

In some aspects, the method can include determining, using at least measured values from or of the HV battery packs, an exact physical location of the isolation breakdown, the measured values including isolation resistance, the battery pack positive voltage, the battery pack negative voltage, and cell voltages.

In some aspects, the method can include determining a total pack voltage by summing a magnitude of the battery pack positive voltage and the battery pack negative voltage.

In some aspects, the method can include determining a total pack voltage by summing the voltage measurements of each cell voltage in a series string.

In some aspects, the method can include calculating the isolation resistance by connecting a known resistance between either the battery pack positive voltage and a chassis ground or the battery pack negative voltage and the chassis ground; and calculating a change in voltage measurement.

In another embodiment, an electric vehicle is disclosed that includes one or more electric motors configured to propel the electric vehicle. A battery system is included to provide power to the one or more electric motors, wherein the battery system includes a battery controller and a plurality of battery modules electrically connected together, each battery module of the plurality of battery modules including a plurality of battery cells positioned within a volume of the battery module. The battery controller can identify an isolation breakdown based at least on whether a low resistance connection exists between a portion of a series connection of the plurality of battery cells and a chassis ground of the electric vehicle; and determine an electrical location of a fault in the plurality of HV battery packs based at least on a battery pack positive voltage and a battery pack negative voltage.

In some aspects, the battery controller can be configured to determine a physical location of the fault based at least on a number of the plurality of battery cells less the battery pack positive voltage divided by an average cell voltage.

In some aspects, the battery controller can be configured to determine a physical location of the fault based at least on voltage measurements of each cell voltage in a series string and positive and/or negative pack voltage.

In some aspects, the battery pack positive voltage is a measurement of a positive-most portion of a series connection of the plurality of battery cells with respect to the chassis ground.

In some aspects, the battery negative voltage is a measurement of a negative-most portion of a series connection of the plurality of battery cells with respect to the chassis ground.

In some aspects, the determining the electrical location of the fault in the plurality of HV battery packs is based at least on cell voltages.

In some aspects, the battery controller can be configured to determine, using at least measured values from or of the HV battery packs, an exact physical location of the isolation breakdown, the measured values including isolation resistance, the battery pack positive voltage, the battery pack negative voltage, and cell voltages.

In some aspects, the isolation resistance is calculated by connecting a known resistance between either the battery pack positive voltage and a chassis ground or the battery pack negative voltage and the chassis ground and calculating a change in voltage measurement.

To the accomplishment of the foregoing and related ends, certain illustrative aspects are described herein in connection with the following description and the appended drawings. These aspects are indicative, however, of but a few of the various ways in which the principles of the claimed subject matter may be employed and the claimed subject matter is intended to include all such aspects and their equivalents. Other advantages and novel features may become apparent from the following detailed description when considered in conjunction with the drawings.

### BRIEF DESCRIPTION OF THE DRAWINGS

The accompanying drawings, which are incorporated in and constitute a part of this specification, illustrate exemplary embodiments of the present disclosure and together with the description, serve to explain the principles of the disclosure.

FIGS. 1A and 1B illustrate an exemplary electric vehicle having a battery system, according to the present disclosure.

FIG. 2 is a schematic illustration of an exemplary battery system of the electric vehicle of FIGS. 1A and 1B, according to the present disclosure.

FIG. 3A is a schematic illustration of an exemplary battery module of the battery system of FIG. 2, according to the present disclosure.

FIG. 3B is a schematic illustration of an exemplary battery housing of the battery system of FIG. 2, according to the present disclosure.

FIG. 4 is a schematic illustration of connections between the battery pack of FIG. 2 and peripheral devices or systems of the electric vehicle of FIGS. 1A and 1B, according to the present disclosure.

FIG. 5 is a flow diagram of a method of determining a location of a fault in a plurality of high-voltage (HV) battery packs of a battery system of an electric vehicle, according to this disclosure.

FIGS. 6A to 6B show implementations of the systems and method of this disclosure for measuring isolation resistance according one example.

FIG. 7 is a schematic illustration of an example battery system according to the present disclosure.

FIG. 8 shows an example graph demonstrating pack voltages during isolation resistance test and showing relatively healthy isolation of the associated battery system according to the present disclosure.

FIG. 9 shows an example graph demonstrating pack voltages during isolation resistance test and showing isolation breakdown of the associated battery system according to the present disclosure.

FIG. 10 illustrates example components of a computing device, according to the present disclosure.

### DETAILED DESCRIPTION

The present disclosure describes a system and method for a battery system including a battery management system (BMS) with a controller configured to identify an isolation breakdown. While principles of the current disclosure are described with reference to an electric vehicle (e.g., the illustrated vehicle is an electric bus), it should be understood that the disclosure is not limited thereto. Rather, the systems and methods of the present disclosure may be used in any vehicle having a battery system (e.g., electric vehicle, electric machine, electric tool, electric appliance, stationary energy storage for grids and mobile energy storage for transportable power, etc.). As used herein, the term “electric vehicle” includes any vehicle or transport machine that is driven at least in part by electricity (e.g., hybrid vehicles, all-electric vehicles, etc.), including heavy duty electric vehicles (e.g., electric buses, electric trucks, electric airplanes, electric boats, etc.) may store and/or consume a large amount of energy compared to smaller electric vehicles (e.g., electric cars, electric bicycles or motorcycles, electric carts, etc.).

Although example embodiments of the disclosed technology are explained in detail herein, it is to be understood that other embodiments are contemplated. Accordingly, it is not intended that the disclosed technology be limited in its scope to the details of construction and arrangement of components set forth in the following description or illustrated in the drawings. The disclosed technology is capable of other embodiments and of being practiced or carried out in various ways.

It must also be noted that, as used in the specification and the appended claims, the singular forms “a,” “an” and “the” include plural referents unless the context clearly dictates otherwise.

In this disclosure, the term “comprising” is synonymous with “including,” “having,” “containing,” or “characterized by.” These terms are inclusive and open-ended and do not exclude additional, unrecited elements or method steps. By using any of these terms, it is meant that at least the named compound, element, particle, or method step is present in the composition or article or method, but does not exclude the presence of other compounds, materials, particles, method steps, even if the other such compounds, material, particles, method steps have the same function as what is named.

In this disclosure, the term “high-voltage” refers to battery systems with battery packs that can rely on a power source that can use more than approximately 60 volts direct current. In some aspects, high-voltage battery packs of this disclosure can form a battery system with at least 400 volts, with at least 800 volts, etc.

In this disclosure, the phrase “consisting of” excludes any element, step, or ingredient not specified in the claim. When this phrase appears in a clause of the body of a claim, rather than immediately following the preamble, it limits only the element set forth in that clause; other elements are not excluded from the claim as a whole.

In this disclosure, the phrase “consisting essentially of” limits the scope of a claim to the specified materials or steps, plus those that do not materially affect the basic and novel characteristic(s) of the claimed subject matter.

In this disclosure, where publications are referenced, the disclosures of these publications in their entireties are hereby incorporated by reference into this application.

In this disclosure, relative terms, such as “about,” “substantially,” or “approximately” are used to indicate a possible variation of ±10% in the stated value.

In describing example embodiments, terminology will be resorted to for the sake of clarity. It is intended that each term contemplates its broadest meaning as understood by those skilled in the art and includes all technical equivalents that operate in a similar manner to accomplish a similar purpose. It is also to be understood that the mention of one or more steps of a method does not preclude the presence of additional method steps or intervening method steps between those steps expressly identified. Steps of a method may be performed in a different order than those described herein without departing from the scope of the disclosed technology. Similarly, it is also to be understood that the mention of one or more components in a device or system does not preclude the presence of additional components or intervening components between those components expressly identified.

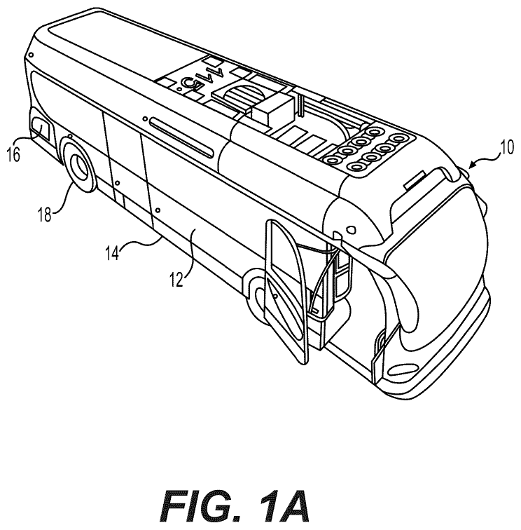

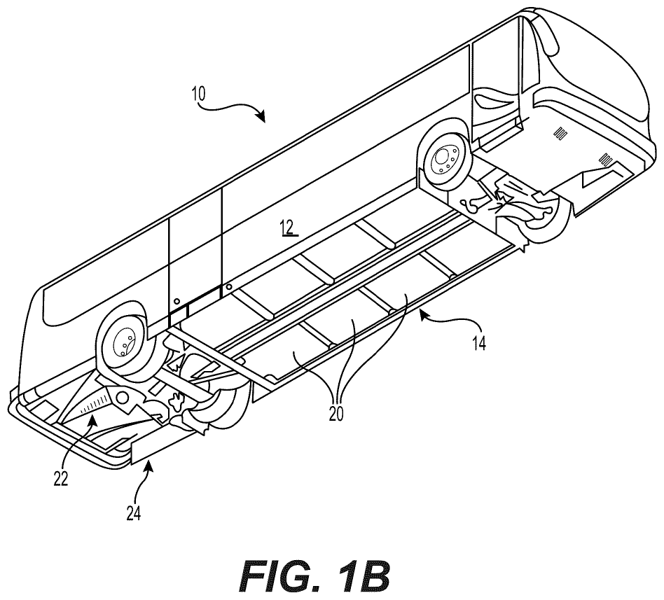

FIGS. 1A and 1B illustrate an electric vehicle 10. FIG. 1A shows the vehicle 10 with its roof visible, and FIG. 1B shows the vehicle 10 with its undercarriage visible. In the discussion below, reference will be made to both FIGS. 1A and 1B. The vehicle 10 may include a body 12 enclosing a space for passengers. In some embodiments, some (or substantially all) parts of the body 12 may be fabricated using one or more composite materials to reduce the weight of the vehicle 10. Without limitation, the body 12 of the vehicle 10 may have any size, shape, and configuration. In some embodiments, the vehicle 10 may be a low-floor electric bus. In a low-floor electric bus, there may be no stairs at the front and/or the back doors of the vehicle 10. In such a vehicle 10, the floor may be positioned close to the road surface to ease entry and exit into the vehicle 10. In some embodiments, the floor height of the low-floor bus may be about 30-45 centimeters from the road surface.

The vehicle 10 may include a powertrain 24 that propels the vehicle 10 along a road surface. The powertrain 24 may include one or more electric motors 22 that generate power, and a transmission that transmits the power to a pair of drive wheels (e.g., wheels 18) of the vehicle 10. A battery system 14 may store electrical energy to power the electric motors 22 of the powertrain 24. In some embodiments, the batteries of the battery system 14 may be configured as a plurality of battery packs 20 positioned in cavities located under the floor of the vehicle 10. In some embodiments, some or all of the battery packs 20 may be positioned elsewhere (e.g., roof) on the vehicle 10. The batteries of the battery system 14 may have any chemistry and construction. The battery chemistry and construction may activate fast charging of the batteries. In some embodiments, the batteries may be lithium titanate oxide (LTO) batteries. In some embodiments, the batteries may be nickel metal cobalt oxide (NMC) batteries. It is also contemplated that, in some embodiments, the batteries may include multiple different chemistries.

The vehicle 10 may include a charging interface. For example, the vehicle 10 may include a charge port (e.g., an electric socket) that is configured to receive a charging plug and charge the vehicle 10 using power from a utility grid. In such embodiments, the vehicle 10 may be charged by connecting the plug to the socket. In some embodiments, the charge port may be a standardized charge port (e.g., a Society of Automotive Engineers (SAE) J1772 charge port) that is configured to receive a corresponding standardized connector (e.g., a SAE J1772 connector). However, in general, the charge port and the mating connector may be of any type and form (custom design or standardized). As illustrated in FIG. 1A, to protect the charge port from the environment (rain, snow, debris, etc.), a hinged lid 16 may cover the charge port when not in use. Additionally, or alternatively, a charging interface may be provided on the roof of the vehicle 10 (not illustrated in FIGS. 1A and 1B) to charge the batteries of the battery system 14. For example, the charging interface may include components that interface with a charging head (e.g., an inverted pantograph that interfaces with a set of rails mounted on the forward rooftop of the vehicle 10) of an external charging station to charge the batteries.

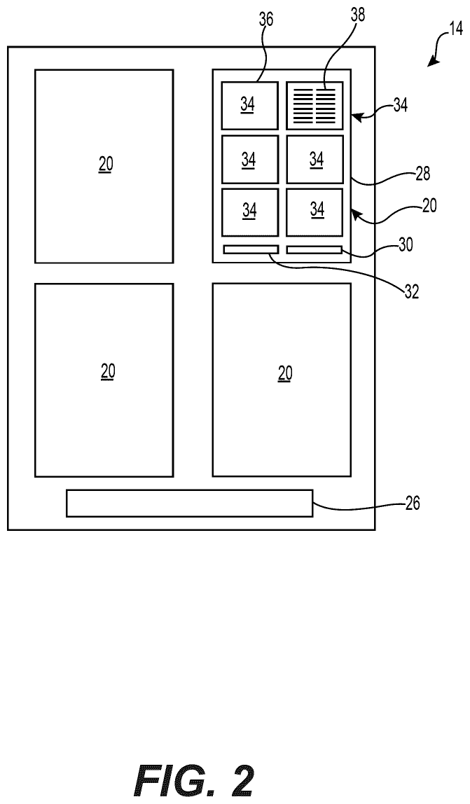

FIG. 2 is a schematic illustration of an exemplary battery system 14 of the vehicle 10 of FIGS. 1A and 1B, according to the present disclosure. The battery system 14 may include a plurality of battery packs 20. Each battery pack 20 may include a plurality of battery modules 34, and each battery module 34 may include a plurality of battery cells 38 arranged therein. In FIG. 2, the inside structure of one of the battery packs 20, and the inside structure of one of the battery modules 34 of the battery pack 20, are shown to aid in the discussion below. The battery cells 38 may have any chemistry and construction. In some embodiments, the battery cells 38 may have a lithium-ion chemistry, sodium-ion, and/or the like. Lithium-ion chemistry comprises a family of battery chemistries that employ various combinations of anode and cathode materials. In automotive applications, these chemistries may include lithium-nickel-cobalt-aluminum (NCA), lithium-nickel-manganese-cobalt (NMC), lithium-manganese-spinel (LMO), lithium titanate (LTO), and lithium-iron phosphate (LFP), for example. In consumer applications, the battery chemistry may also include lithium-cobalt oxide (LCO), for example.

The plurality of battery packs 20 of the battery system 14 may be connected together in series or in parallel. In some embodiments, these battery packs 20 may also be arranged in strings. For example, the battery system 14 may include multiple strings connected in parallel, with each string including multiple battery packs 20 connected together in series. Configuring the battery system 14 as parallel-connected strings may allow the vehicle 10 to continue operating with one or more strings disconnected if a battery pack 20 in a string fails or experiences a problem. The plurality of battery modules 34 in each battery pack 20, and the plurality of battery cells 38 in each battery module 34, may also be electrically connected together in series or parallel. In some embodiments, some of the battery modules 34 in a battery pack 20 may be connected together in series, and groups of the series-connected battery modules 34 connected together in parallel.

Similarly, in some embodiments, a group of battery cells 38 in each battery module 34 may be connected together in series to form multiple series-connected groups of battery cells 38, and these series-connected groups may be connected together in parallel. That is, some or all battery packs 20 in the battery system 14 may include both series-connected and parallel-connected battery modules 34, and some or all battery modules 34 in each battery pack 20 may include both series-connected and parallel-connected battery cells 38. In some embodiments, each battery pack 20 of the battery system 14 may be substantially identical (in terms of number of battery modules 34, number of battery cells 38 in each battery module 34, how the battery modules 34 are connected, etc.) to each other. In other embodiments, one or more of the battery packs 20 of the battery system 14 may have a different configuration than one or more other battery packs 20 of the battery system 14.

In general, the battery packs 20 of the battery system 14 may be physically arranged in any manner. In some embodiments, the battery packs 20 may be arranged in a single layer on a common horizontal plane to decrease the height of the battery system 14, so that it may be positioned under the floor of the low-floor vehicle 10. For example, the battery packs 20 may have a height less than or equal to about 18 centimeters, to allow the battery system 14 to be accommodated under the floor of the low-floor vehicle 10. The low height profile of the battery system 14 may allow the battery system 14 to be more aerodynamic, and may increase its surface area relative to the number of battery cells 38, which may increase heat dissipation and improve temperature regulation. In general, the battery system 14 may be configured to store any amount of energy and to export or import electrical power (in terms of Watts (W)) at a voltage (V). Increasing the amount of energy stored in the battery system 14 may increase the distance that the vehicle 10 can travel between recharges. In some embodiments, the number of the battery packs 20, the battery modules 34, the battery cells 38, and the chemistry of the battery cells 38, etc. may be configured such that the total energy capacity of the battery system 14 may be between, for example, about 40kWh and to greater than 1MWh.

In general, the battery system 14 may have any number (e.g., 1, 2, 3, 4, 6, 8, 10, etc.) of battery packs 20. In some embodiments, the number of battery packs 20 in the battery system 14 may be between about 2 and 6. Each battery pack 20 may have a protective housing 28 that encloses the plurality of battery modules 34 (and other components of the battery pack 20) therein. Although the battery pack 20 of FIG. 2 is illustrated as including six battery modules 34 arranged in two columns, this is merely an example. In general, any number (e.g., 1, 4, 5, 6, 8, 10, 12, 14, 16, 18, 20, 22, 24, etc.) of battery modules 34 may be provided in a battery pack 20, and each battery module 34 may include any number of battery cells 38 (e.g., 1, 100, 101, 200, 300, 400, 500, 600, 800, etc.) arranged in any manner. In some embodiments, the number of battery modules 34 in each battery pack 20 may be between about 10 and 20, and the number of battery cells 38 housed in each battery module 34 may be between about 400 and 700. In some embodiments, the battery modules 34 housed in the housing 28 of a battery pack 20 may be separated from each other with dividers (not shown) that provide electrical and thermal insulation. The dividers may protect the other battery modules 34 if any battery module 34 fails (e.g., experiences a high temperature event). The dividers may be made of a material that does not oxidize or otherwise become damaged when exposed to electrical arcs and/or high temperatures.

The housing 28 of each battery pack 20 may have a box-like structure, and may be shaped to allow the battery modules 34 of the battery pack 20 to be arranged the battery modules 34 of the battery pack 20 to be arranged to maximize the volume available within the vehicle of the battery system 14. In some aspects, the battery modules 34 of the battery pack 20 can be arranged in a single layer on a common horizontal plane to decrease the height of the battery pack 20. In some embodiments, the housing 28 may be watertight (e.g., to about 1 meter) and may have a rating for dust and water resistance (e.g., an International Protection (IP) 67 rating). The housing 28 may be configured to contain any failures (e.g., electric arcs, fires, etc.) within the battery pack 20 in order to prevent damage to other battery packs 20 or other portions of the vehicle 10 if a component inside a battery pack 20 fails. In some embodiments, the housing 28 may be constructed of corrosion and puncture resistant materials. For example, the materials of which the housing 28 may be constructed may include composite materials, Kevlar, stainless steel, aluminum, high strength plastics, etc.

In addition to the battery modules 34, the housing 28 may also enclose a battery management system (BMS) 30 that monitors or controls the operation of the battery modules 34 and a thermal management system 32 that assists in managing the temperature of the battery modules 34 of the battery pack 20 (e.g., heat, cool, etc.). As described in more detail elsewhere herein, the BMS 30 and/or one or more other pack controllers may monitor the state (e.g., humidity, state of charge (SOC), current, temperature, etc.) of the battery modules 34 and the battery cells 38 in the battery pack 20, and may control the operations of the battery pack 20 to ensure that power is safely and efficiently directed into and out of the battery pack 20. The thermal management system 32 may include components that vent, circulate air and/or a liquid coolant to the battery modules 34 to heat or cool the battery modules 34. These components may include, for example, circulating fans, coolant conduits, heat exchangers, etc. that assist in circulating air and/or a coolant through the battery modules 34 packaged in the housing 28 to manage the temperature of the battery pack 20.

The battery system 14 may include an energy storage management (ESM) system 26 that communicates with the BMS 30 included in the battery pack 20 to control the operation of the battery system 14 on a per-battery pack 20 basis. The ESM system 26 may include circuit boards, electronic components, sensors, and controllers that monitor the performance of the components (e.g., the battery packs 20, the battery modules 34, and the battery cells 38) of the battery system 14 based on sensor input (e.g., voltage, current, temperature, humidity, etc.), provide feedback (e.g., alarms, alerts, etc.), and control the operation of the battery system 14 for safe and efficient operation of the vehicle 10. In some embodiments, the ESM system 26 may perform charge balancing between different battery packs 20, battery modules 34 and/or battery cells 38 during recharging or during operation of the vehicle 10. The ESM system 26 may also thermally and/or electrically isolate sections (e.g., battery cells 38, battery modules 34, battery packs 20, etc.) of the battery system 14 when one or more sensor readings (e.g., temperature, etc.) exceed a threshold value. As will be described in more detail elsewhere herein, in some embodiments, the ESM system 26 may initiate or control energy discharge from all or selected battery packs 20, battery modules 34, or battery cells 38 based on the occurrence of predefined trigger events.

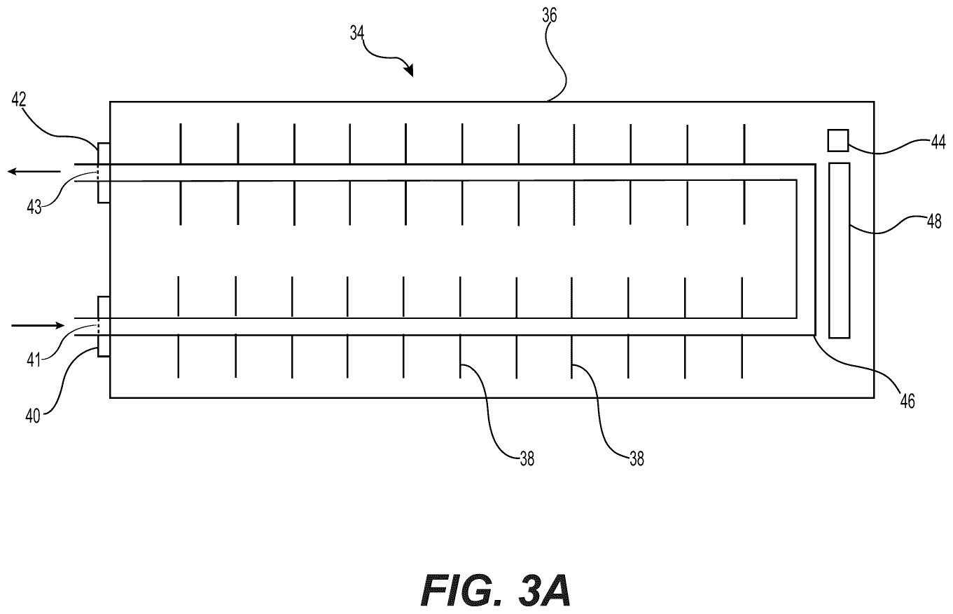

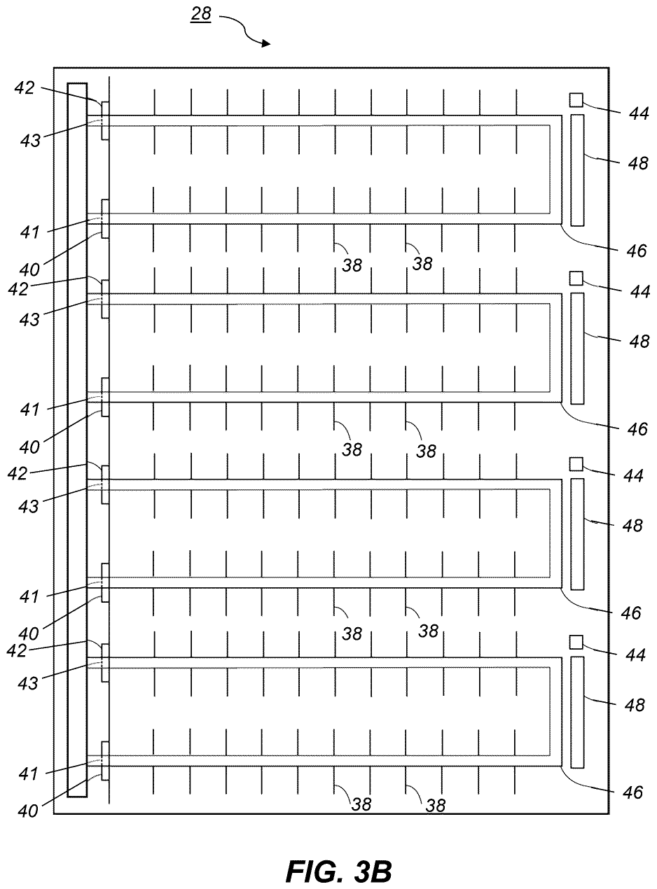

FIG. 3A is a schematic illustration of an exemplary battery module 34 of the battery system 14 of FIG. 2, according to the present disclosure. The battery module 34 includes a casing 36 that encloses the plurality of battery cells 38 of the battery module 34 therein. Similar to the housing 28 of the battery pack 20, the casing 36 may be configured to contain any failures (e.g., electric arcs, fires, etc.) of the battery cells 38 of the battery module 34 within the casing 36 in order to prevent the damage from spreading to other battery modules 34 of the battery pack 20. The casing 36 may be made of any material suitable for this purpose. In some embodiments, the casing 36 may be constructed of one or more of materials such as, for example, Kevlar, aluminum, stainless steel, composite materials, etc. In some embodiments, the casing 36 may be substantially air-tight to hermetically seal the battery cells 38 of the battery module 34 therein.

In general, the battery cells 38 may have any shape and structure (e.g., a cylindrical cell, a prismatic cell, a pouch cell, etc.). Typically, all the battery cells 38 of a battery module 34 may have the same shape. However, it is also contemplated that different shaped battery cells 38 may be packed together in the casing 36 of a battery module 34. In addition to the battery cells 38, the casing 36 may also include sensors (e.g., a temperature sensor, a voltage sensor, a humidity sensor, etc.) and controllers (e.g., a battery module controller 44) that monitor and control the operation of the battery cells 38. Although not illustrated, the casing 36 also may include electrical circuits (e.g., voltage and current sense lines, low voltage lines, high voltage lines, etc.), and related accessories (e.g., fuses, switches, etc.), that direct electrical current to and from the battery cells 38 during recharging and discharging.

As explained previously, the battery cells 38 of the battery module 34 may be electrically connected together in any manner (e.g., in parallel, in series, or in groups of series-connected battery cells 38 connected together in parallel). These battery cells 38 may also be physically arranged in any manner. In some embodiments, the battery cells 38 of a battery module 34 may be packed together tightly to fill the available volume within the casing 36. In some embodiments, the battery cells 38 may be arranged together to form multiple groups (e.g., bricks) of battery cells 38 electrically connected together in series. The multiple bricks (each comprising multiple battery cells 38 electrically connected together) may then be electrically connected together (e.g., in series or parallel) and packaged together in the casing 36. In some embodiments, one or more sensors may be associated with each brick of the battery module 34. Terminals (e.g., positive and negative terminals) electrically connected to the battery cells 38 of the battery module 34 may be provided on an external surface of the casing 36.

The casing 36 may also include a coolant loop 46 configured to circulate a coolant through the battery module 34. The coolant loop 46 may comprise fluid conduits arranged to pass through, or meander (e.g., zigzag) through, the volume enclosed by the casing 36. An inlet port 40 and an outlet port 42 of the casing 36 may fluidly couple the coolant loop 46 to a coolant circuit of the battery system 14. The coolant may enter the coolant loop 46 through the inlet port 40 and may exit the casing 36 through the outlet port 42. In some embodiments, where the battery module 34 is air cooled, the casing 36 may also include inlet and outlet vents configured to direct cooling air into and out of the casing 36. In some embodiments, the coolant may cool all the battery modules 34 of a battery pack 20 before exiting the battery pack 20. That is, the coolant loops 46 of the battery modules 34 of the battery pack 20 may be connected in series such that the coolant exiting one battery module 34 enters the coolant loop 46 of another battery module 34. In some embodiments, coolant may be directed into each battery module 34 individually (for e.g., from a common coolant gallery of the battery pack 20). In some embodiments, groups of battery modules 34 within a battery pack 20 may be fluidly connected in series and multiple series-connected battery modules 34 may be connected together in parallel.

During operation of the battery system 14, the battery cells 38 of the battery module 34 release heat. This released heat may be transferred to the coolant circulating through the coolant loop 46 and then removed from the casing 36 along with the coolant. In general, any known fluid may be used as the coolant. In some embodiments, water (with suitable additives such as antifreeze, etc.) or another suitable liquid may be used as the coolant. The battery cells 38 of the battery module 34 may be arranged to enhance heat dissipation into the coolant circulating through the battery module 34. For example, in some embodiments, the battery cells 38 may be in close thermal contact with the coolant loop 46. In some embodiments, the battery cells 38 may be placed in close thermal contact with metal plates that serve as heat conducting pathways to the coolant loop 46.

FIG. 3B is an example schematic illustration of an exemplary cell-to-pack battery housing 28 example of the battery system 14 of FIG. 2, according to the present disclosure, with similar features as in the example of FIG. 3A. In the depicted example of housing 28, a casing 36 encloses groups of cells 38 and fluid loops 46 arranged directly into housing 28 of system 14. In some aspects, knowledge of the physical arrangement of battery cells within the pack and the electrical location of the isolation fault can be used to determine the physical location of the fault within the battery pack.

The battery module 34 and/or housing 28 may also include one or more heaters 48 positioned within the casing 36 (or in close thermal contact with the casing 36). In general, any type of heating device (e.g., a resistance heater, a positive temperature coefficient (PTC) heater, etc.) may be used as the heater 48. In some embodiments, the heater 48 may be a PTC cartridge heater. Unlike a resistance heater which generates heat at a constant rate, a PTC heater may use PTC resistive elements which generate heat at a lower rate at higher temperatures. Therefore, a PTC heater is self-regulating to a fixed working temperature.

In some embodiments, the heater 48 (or the multiple heaters 48) of each battery module 34 may be powered solely by the battery cells 38 of that battery module 34 and/or housing 28. The heater 48 may be activated by the battery module controller 44 and/or by another controller (e.g., the ESM system 26, the BMS 30, etc.) of the battery system 14. When the heater 48 is activated, it generates heat using the energy stored in the battery cells 38 of that battery module 34 and/or housing 28. Consequently, the stored energy (or SOC) of the battery cells 38 in the battery module 34 decrease as a result of activation of the heater 48. The heat dissipated by the heater 48 may be removed from the battery module 34 and/or housing 28 by the circulating coolant (or by conduction). A temperature sensor (or thermistor) of the battery module 34 and/or housing 28 may monitor the heat dissipated by the heater 48.

The heater 48 may be positioned at any location within the casing 36. In general, the location of the heater 48 may be selected such that the maximum energy discharged by the heater 48 does not damage (or jeopardize the safety of) the battery cells 38 of the battery module 34 and/or housing 28. Therefore, in some embodiments, the heater 48 may be spaced away from (i.e., not directly in contact with) the battery cells 38 such that the heater 48 is thermally isolated from the battery cells 38. The location of the heater 48 may also be selected such that the dissipated heat can be easily transferred to the body of the battery pack 20 (thus allowing the heater 48 to dissipate more heat without a resulting increase in temperature). Therefore, in some embodiments, the heater 48 may be positioned in direct contact with the metal frame of the battery pack 20 to enhance heat conduction. In some embodiments, the heater 48 may be positioned close to (as illustrated in FIGS. 3A and 3B) the coolant loop 46 so that the dissipated heat may be easily transferred to the coolant circulating through the coolant loop 46. It is also contemplated that, in some embodiments, the heater 48 may be positioned within the coolant loop 46 (i.e., submerged in the coolant of the coolant loop 46). In some embodiments, as illustrated in FIGS. 3A and 3B, the heater 48 may be positioned about midway of the coolant loop 46. That is, the heater 48 may be positioned proximate to (on within) the coolant loop 46, and substantially equidistant from the inlet port 40 and the outlet port 42.

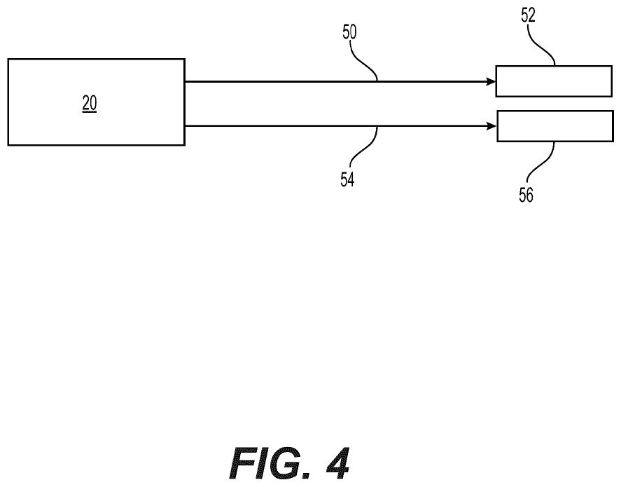

FIG. 4 is a schematic illustration of connections between the battery pack 20 of FIG. 2 and peripheral devices or systems of the vehicle 10 of FIGS. 1A and 1B, according to the present disclosure. As illustrated, the schematic in FIG. 4 includes the battery pack 20, a high voltage bus bar 50, a high voltage peripheral device or system 52, a low voltage bus bar 54, and a low voltage peripheral device or system 56. The battery pack 20 may be electrically connected (e.g., through one or more electrical terminals 62, 66 not illustrated in FIG. 4) to the high voltage bus bar 50. The high voltage bus bar 50 may provide one or more electrical connections between the battery pack 20 and the high voltage peripheral device or system 52 for carrying high voltage power (e.g., at greater than or equal to approximately 60 V) from the battery pack 20 to the high voltage peripheral device or system 52. The high voltage peripheral device or system 52 may include, for example, devices or systems of the vehicle 10 used during operation of the vehicle 10, such as the powertrain 24, an heating, ventilation, and air conditioning (HVAC) system, an external DC/DC system, or the like.

Similarly, the battery pack 20 may be electrically connected to the low voltage bus bar 54. The low voltage bus bar 54 may provide one or more electrical connections between the battery pack 20 and the low voltage peripheral device or system 56 for carrying low voltage power (e.g., at less than 60 V) from the battery pack 20 to the low voltage peripheral device or system 56. The low voltage device or system 56 may include, for example, devices or systems that are operational when the vehicle 10 is not in use or is in an idle state, such as a fire suppression system, a security system, a lighting system, an indicator, a cooling pump, or the like. In some implementations, the low voltage device or system 56 may include any device or system of the vehicle 10 that does not operate on a high voltage energy storage system.

Although FIG. 4 illustrates a single battery pack 20, there may be multiple battery packs 20 electrically connected to the high voltage bus bar 50 or the low voltage bus bar 54, and the multiple battery packs 20 may be organized into electrically parallel strings of battery packs 20 (with the battery packs 20 included in a string connected in series). In addition, the illustration of a single high voltage peripheral device or system 52 and a single low voltage peripheral device or system 56 is merely exemplary and some embodiments may include multiple high voltage peripheral devices or systems 52 and/or multiple low voltage peripheral devices or systems 56.

In some aspects, to measure isolation resistance of the high-voltage within a battery enclosure, industry practice can be for the BMS to use approaches described in internationally recognized specifications like ISO 6469-3, which is incorporated herein by reference. In this approach, a vehicle can choose to rely on the BMS to measure the isolation of the high voltage system external of the battery when the HV battery terminals are energized and powering the vehicle. Yet, HV batteries that contains a breakdown in isolation can lose their ability to protect service personnel, including from shock and arc flash in the event of mistake during repair. When servicing a battery that contains an isolation fault, service personnel must typically wear arc flash and shock rated personal protective equipment (PPE) to protect them in the event of another failure. This PPE can be uncomfortable and cumbersome to wear while performing intricate repair work. The longer service personnel are exposed to this hazard the more at risk they are creating an additional fault that would result in an arc flash. The hazard only increases with voltage levels. Having exact knowledge of where the fault exists and how to isolate it, can advantageously reduce the need for prolonged exposure to hazards during the repair process.

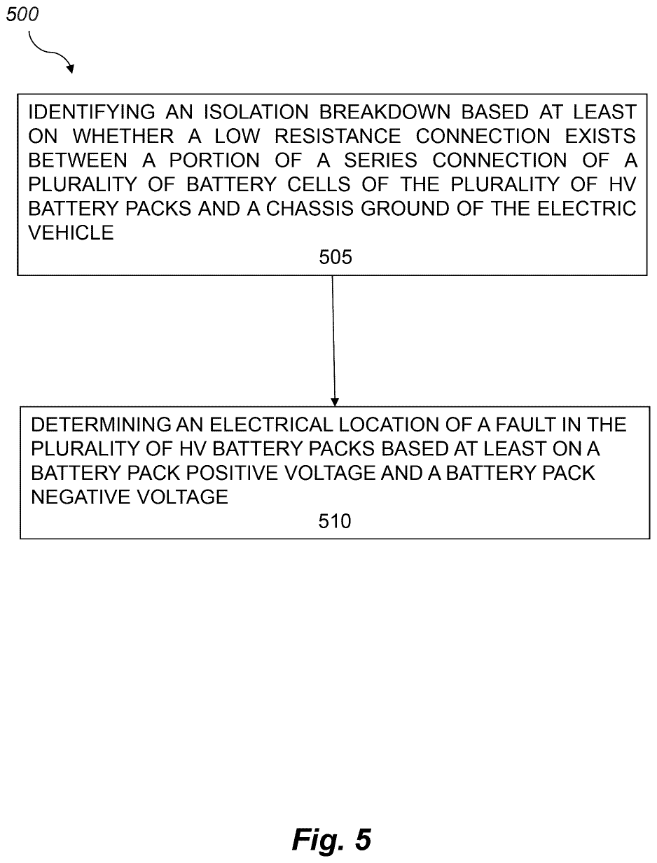

Turning to FIG. 5, an exemplary method 500 for determining a location of a fault in a plurality of high-voltage (HV) battery packs of a battery system of an electric vehicle, according to this disclosure. According to one embodiment, the method 500 includes one or more of the following steps. In step 505, the method includes identifying an isolation breakdown based at least on whether a low resistance connection exists between a portion of a series connection of a plurality of battery cells of the plurality of HV battery packs and a chassis ground of the electric vehicle. In step 510, the method includes determining an electrical location of a fault in the plurality of HV battery packs based at least on a battery pack positive voltage and a battery pack negative voltage.

In method 500, the determining the electrical location of the fault in the plurality of HV battery packs can be based at least on cell voltages.

The method 500 can include determining a physical location of the fault based at least on a number of the plurality of battery cells less the battery pack positive voltage divided by an average cell voltage.

Additionally, the method 500 can determining a physical location of the fault based at least on voltage measurements of each cell voltage in a series string.

In some aspects, the method 500 can include determining, using at least measured values from or of the HV battery packs, an exact physical location of the isolation breakdown, the measured values comprising isolation resistance, the battery pack positive voltage, the battery pack negative voltage, and cell voltages.

In some aspects, the method 500 can include determining a total pack voltage by summing a magnitude of the battery pack positive voltage and the battery pack negative voltage.

In some aspects, the method 500 can include calculating the isolation resistance by connecting a known resistance between either the battery pack positive voltage and a chassis ground or the battery pack negative voltage and the chassis ground; and calculating a change in voltage measurement.

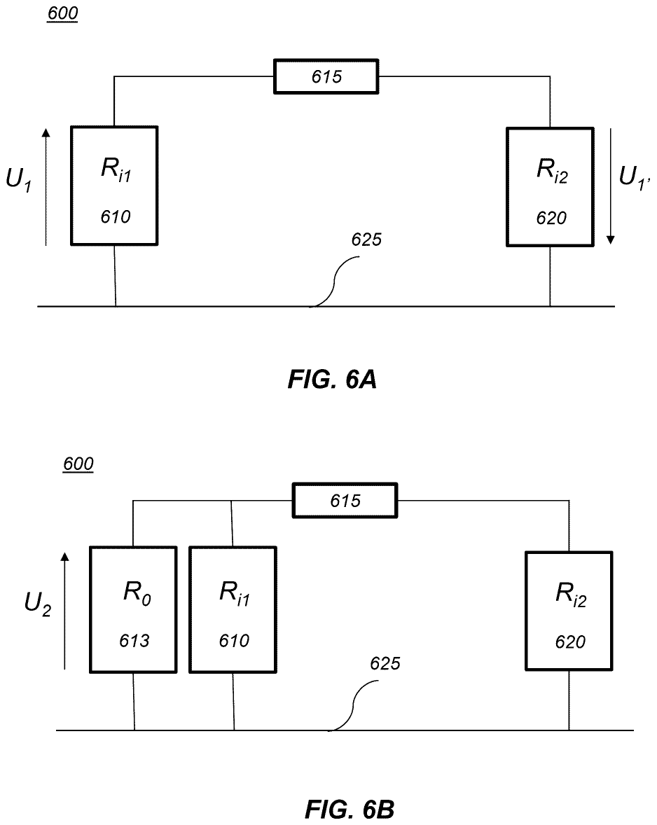

Turning to FIGS. 6A to 6B, one example is illustrated for measuring isolation resistance to determine a location of a fault in one or more HV battery packs of a battery system, according to example implementations, such as with renewable energy resources (RESs), fuel cell stacks, and the like. In FIG. 6A, Rᵢ₁ and Rᵢ₂ are considered fictious isolation resistances between terminals of power source 615 and chassis 625, whereby Rᵢ₂ is the lower isolation resistance and is thus the isolation resistance Rᵢ to be determined. According to FIGS. 6A to 6B, in a first step the voltage U_{EPS} is measured between negative and positive terminals of source 615. In another step, the voltages, U₁ and U_{1′}, are measured between each terminal of source 615 and chassis 625. A known measuring resistance, Rₒ, can be added parallel to Rᵢ₁ and voltage U₂ can be measured and the test voltage can be stable. In some aspects, Rₒ can be selected so that a predetermined accuracy is achieved for the measured voltages on the calculated isolation resistances. Rₒ can be the value (Ω) of a minimum required isolation resistance (Ω/V) multiplied by a maximum working voltage of power source 615 or voltage class (e.g., B2 electric circuit) that includes source 615±20%. In some aspects, Rₒ is not required to be precisely this value; however, an Rₒ value in this range can provide an appropriate voltage range for the voltage measurements. In turn, isolation resistance Rᵢ can be calculated using Rₒ and voltages U1, U1′, and U_{2.} In some instances, isolation resistance Rᵢ can be calculated using the following formula: Rᵢ=R0×U_{EPS}×(1/U₂-1/U₁) , where U_{EPS} is the voltage from power source 615 and U₂ is the voltage measured when Rₒ has been added to the circuit.

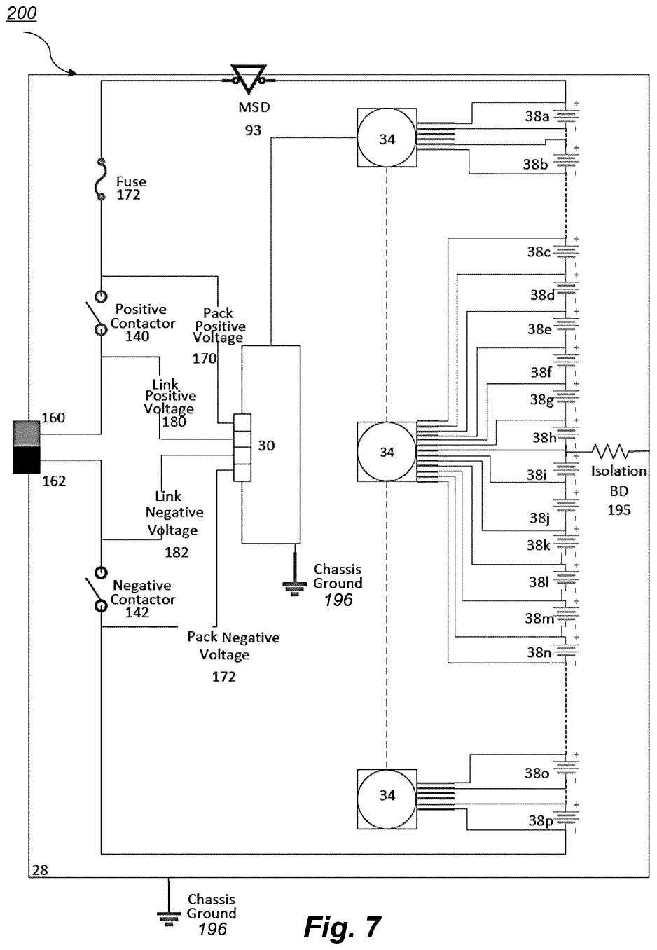

FIG. 7 illustrates another exemplary electrical schematic of a battery pack system 200 according to the present disclosure. Similar to FIG. 3B, system 200 can include an enclosure 28 that houses a plurality of battery modules 34 each having a plurality of cells 38 (e.g., 38a to 38p). System 200 can include one or more additional components not illustrated in FIG. 7 (or elsewhere herein), such as a high voltage bus bar, a low voltage bus bar, positive electrical connections, positive electrical terminals, negative electrical connections, negative electrical terminals, software layer communication lines, a hardware layer communication line, and other electrical connections. As FIG. 7 is merely illustrative of one example, fewer or greater number of modules 34 and corresponding cells 38 can be included as needed or required. System 200 can include BMS 30 that can be electrically connected to modules 34. BMS 30 can include circuitry and logic for managing functionality of modules 34, including power distribution functionality, perform isolation monitoring, charging functionality, monitoring current, controlling contactors (e.g., positive contactor 140, negative contactor 142, monitor pack positive voltage 170, pack negative voltage 172, link negative voltage 182, link positive voltage, fuse 172, and MSD 93 high voltage measurements, and/or the like). In some aspects, BMS 30 can be configured to monitor the above-referenced aspects individually in each pack module 34 and/or individual cells 38 thereof. In some aspects, contactors 140, 142 can facilitate an isolation monitoring circuit at BMS 30 and/or be included in system 200 for galvanic isolation thereby ensuring that arcing and shock does not occur during handling. In some aspects, fuse 172 can be configured to interrupt the electrical circuit upon a particular trigger, such as involvement of a vehicle containing the battery system in an accident. Upon detection of the trigger, BMS 30 can transmit a trigger signal to fuse 172 to disconnect corresponding module 34 and/or cells 38 to prevent short circuiting and/or fire.

BMS 30 can be configured to communicate with modules 34 and corresponding cells 38 to identify isolation breakdown 195. As described in this disclosure, pack positive voltage 170 can be the measurement of the most positive portion of the series connection of cells 38 with respect to chassis ground 196. Pack voltage negative 172 can be the measurement of the most negative portion of the series connection of cells 38 with respect to chassis ground 196. In turn, the sum of the magnitude of these voltages 170, 172 can equal a total pack voltage. During operation, once a cell location 195 of the isolation fault is known, this information can be combined with knowledge of the architecture of system 200 and mechanical architecture to further diagnose location 195 of the fault and operations to isolate it safely and quickly.

In some aspects, the fault can be calculated down to a specific module according to the following: floor (Cell fault number/cells per module) and Cell Number=Cell fault number−(module number*cells per module). In one example implementation, system 200 can include 180 series cells (e.g., cells 38) and 15 series modules (e.g., module 34), with each module 34 having 12 cells each. The system can identify a fault located at cell number 126 and a fault located at module number 10, cell number 6 (floor(126/12))=10, 126−(12*10)=6. As a result of these determinations, isolation operation instructions can be transmitted to isolate module number 10 from the rest of the series connection of modules.

In some aspects, where cell voltages may not all be equal, a fault location can be calculated using BMS 30 to recursively subtract cell voltages from the pack positive voltage 170 until the result is close to 0. In turn, a fault can be deemed to reside at a location after the last subtraction that results in 0. For example, a fault voltage can be Positive Pack Voltage and X can be a total cell count, where a fault voltage can be defined by a fault voltage minus cell Voltage(X) while the fault voltage is >0. The X can be the cell fault number.

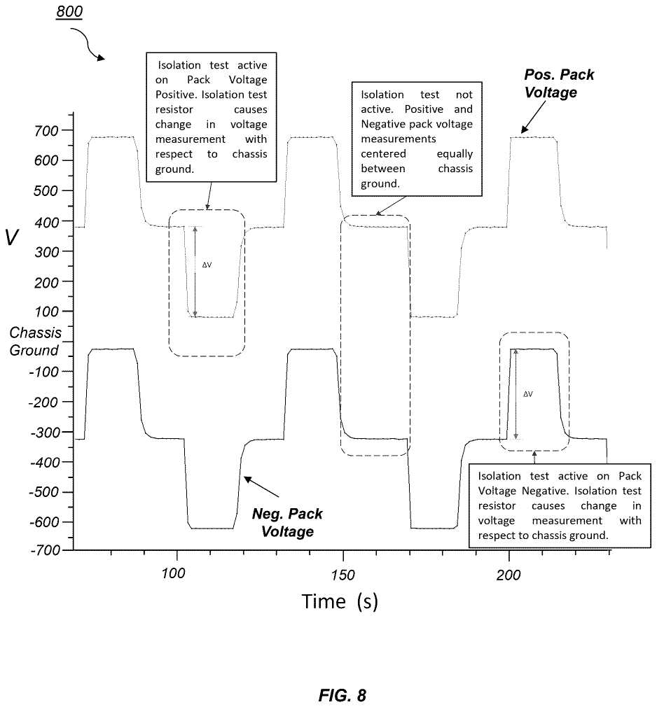

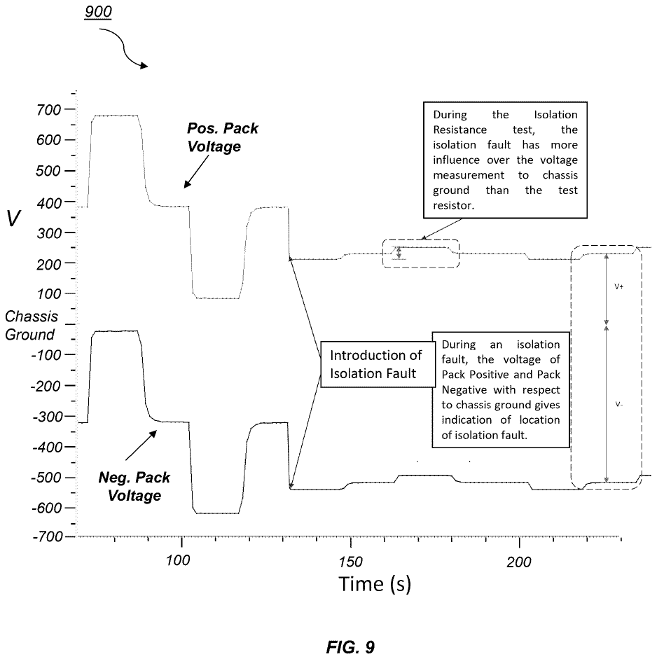

FIG. 8 shows an example graph 800 demonstrating pack voltages during isolation resistance test and showing relatively healthy isolation of the associated battery system (e.g., system 200) while FIG. 9 shows an example graph 900 demonstrating pack voltages during isolation resistance test and showing isolation breakdown of the associated battery system (e.g., system 200). In some aspects, batteries with relatively high levels of isolation (greater than 10,000 Ω/V) can experience relatively large changes in voltage measurement (±Pack Voltage) before and during isolation resistance testing, such as in FIG. 8. During operations, if an isolation breakdown exists (e.g., isolation breakdown 195 of FIG. 7), then there can be a low resistance connection between a portion of the series connection of cells 38 and the chassis ground 196. In turn, a resulting pack voltage positive 170 and negative 172 measurements can fluctuate less, as shown in FIG. 9. If this occurs, then the isolation fault can be located electrically between voltages 170 and 172.

In one example, a battery pack with a measured pack voltage of 720V DC can have a positive voltage measurement of 216V and negative voltage measurement of −504V. Based on these inputs, the isolation fault can exist at 216V from a most positive electrical connection of the series string of cells (e.g., cells 38 of system 200 of FIG. 7). To determine a physical location of the isolation fault, the BMS (e.g., BMS 30) can consider the voltage measurements of each cell voltage in the series string, where pack voltage is the sum of all cell voltages from 1 to N where cell N is most positive and cell 1 is most negative. In some aspects, the physical location of the isolation fault can be calculated as follows: cell number ~N−(Pack Voltage positive/average cell voltage). By way of example only, then the 720V battery of this illustration can have a total of 180 cells in series and each cell can be at 4V so that the location of the isolation fault can exist at cell number 126 (e.g., 180-216V /4V).

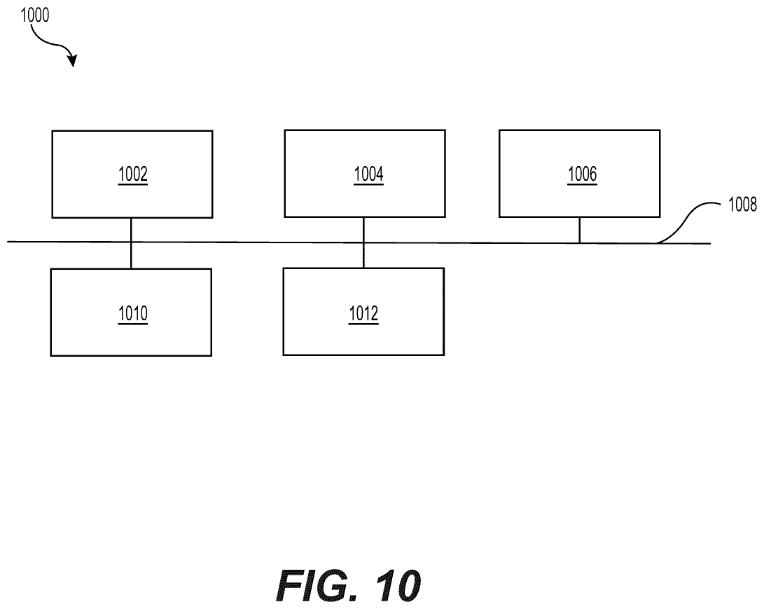

FIG. 10 illustrates example components of a computing device 1000, according to the present disclosure. In particular, FIG. 10 is a simplified functional block diagram of a computing device 1000 that may be configured as a device for executing methods of this disclosure, such as FIGS. 10 and 11. For example, the computing device may be configured as the ESM system 26, the BMS 30, a battery pack controller, the high voltage peripheral device or system 52, the low voltage peripheral device or system 56, and/or another device or system according to exemplary embodiments of the present disclosure. In various embodiments, any of the devices or systems described herein may be the computing device 1000 illustrated in FIG. 10 and/or may include one or more of the computing devices 1000.

As illustrated in FIG. 10, the computing device 1000 may include a processor 1002, a memory 1004, an output component 1006, a communication bus 1008, an input component 1010, and a communication interface 1012. The processor 1002 may include a central processing unit (CPU), a graphics processing unit (GPU), an accelerated processing unit (APU), a microprocessor, a microcontroller, a digital signal processor (DSP), a field-programmable gate array (FPGA), an application-specific integrated circuit (ASIC), or another type of processing component. In some embodiments, the processor 1002 includes one or more processors capable of being programmed to perform a function. The memory 1004 may include a random access memory (RAM), a read only memory (ROM), and/or another type of dynamic or static storage device (e.g., a flash memory, a magnetic memory, and/or an optical memory) that stores information and/or instructions for use by the processor 1002.

The output component 1006 may include a component that provides output information from the computing device 1000 (e.g., a display, a speaker, and/or one or more light-emitting diodes (LEDs)). The communication bus 1008 may include a component that permits communication among the components of the computing device 1000. The input component 1010 may include a component that permits the computing device 1000 to receive information, such as via user input (e.g., a touch screen display, a keyboard, a keypad, a mouse, a button, a switch, and/or a microphone). Additionally, or alternatively, the input component 1010 may include a sensor for sensing information (e.g., a global positioning system (GPS) component, an accelerometer, a gyroscope, and/or an actuator). The communication interface 1012 may include a transceiver-like component (e.g., a transceiver and/or a separate receiver and transmitter) that activates device 1000 to communicate with other devices, such as via a wired connection, a wireless connection, or a combination of wired and wireless connections. The communication interface 1012 may permit the computing device 1000 to receive information from another device and/or provide information to another device. For example, the communication interface 1012 may include a controller area network (CAN) bus, an Ethernet interface, an optical interface, a coaxial interface, an infrared interface, a radio frequency (RF) interface, a universal serial bus (USB) interface, a wireless local area network interface, a cellular network interface, and/or the like.

As noted above, the computing device 1000 illustrated in FIG. 10 may perform one or more processes described herein. The computing device 1000 may perform these processes based on the processor 1002 executing software instructions stored by a non-transitory computer-readable medium, such as the memory 1004 and/or another storage component. For example, the storage component may include a hard disk (e.g., a magnetic disk, an optical disk, a magneto-optic disk, and/or a solid state disk), a compact disc (CD), a digital versatile disc (DVD), a floppy disk, a cartridge, a magnetic tape, and/or another type of non-transitory computer-readable medium, along with a corresponding drive. A computer-readable medium is defined herein as a non-transitory memory device. A memory device includes memory space within a single physical storage device or memory space spread across multiple physical storage devices.

Software instructions may be read into the memory 1004 and/or a storage component from another computer-readable medium or from another device via the communication interface 1012. When executed, software instructions stored in the memory 1004 and/or the storage component may cause the processor 1002 to perform one or more processes described herein. Additionally, or alternatively, hardwired circuitry may be used in place of or in combination with software instructions to perform one or more processes described herein. Thus, embodiments described herein are not limited to any specific combination of hardware circuitry and software.

Systems and methods of this disclosure are contemplated for use with battery packs and battery systems, especially volume-sensitive applications such as vehicular applications. Battery packs configured according to the present disclosure may be significantly thinner than other battery packs, thereby occupying less volume. The thinner configuration of battery packs disclosed herein may further increase design flexibility for vehicles and other machines incorporating battery. For example, a vehicle designer need not necessarily allocate a central, high volume space for a battery system, but rather may distribute the thinner battery packs throughout the vehicle in a less intrusive manner, such as by lining a floor or headliner of the vehicle with battery packs. Additionally, by configuring each battery pack to connect through a single circuit board and electrical connection cable to a centralized battery management device, modularity and flexibility of a battery system can be greatly improved. For example, battery packs may be added or subtracted from any given battery system depending on power needs essentially with plug-and-play effort.

With relatively small and modular battery packs (e.g., at least 40 kWh in some aspects), the herein disclosed systems are configured to serve a variety of commercial vehicle applications (e.g., electric buses, large vehicles, etc.). The gravimetric energy density of the disclosed embodiments allows weight sensitive commercial vehicle applications to give back more available payload to the vehicle, while the volumetric energy density allows increased onboard energy to satisfy all the routes and duty cycles.

While principles of the present disclosure are described herein with reference to voltage battery isolation fault diagnosis systems and methods for a battery pack, it should be understood that the disclosure is not limited thereto. Rather, the systems and methods described herein may be employed in any type of system, battery, as well as use cases such as electric vehicle or anything with a battery system. Also, those having ordinary skill in the art and access to the teachings provided herein will recognize additional modifications, applications, embodiments, and substitution of equivalents all fall within the scope of the embodiments described herein. Accordingly, the invention is not to be considered as limited by the foregoing description. For example, while certain features have been described in connection with various embodiments, it is to be understood that any feature described in conjunction with any embodiment disclosed herein may be used with any other embodiment disclosed herein.

What is claimed is:

1. A battery system of an electric vehicle, comprising:
a plurality of high-voltage (HV) battery packs, each HV battery pack comprising a plurality of battery cells enclosed within a housing; and
a battery management system (BMS) electrically connected to each of the HV battery packs configured to control the plurality of HV battery packs, the BMS comprising a controller configured to:
identify an isolation breakdown based at least on whether a low resistance connection exists between a portion of a series connection of the plurality of battery cells and a chassis ground of the electric vehicle; and
determine an electrical location of a fault in the plurality of HV battery packs based at least on a battery pack positive voltage and a battery pack negative voltage.

2. The battery system of claim 1, the controller of the BMS is configured to:
determine a physical location of the fault based at least on a number of the plurality of battery cells less the battery pack positive voltage divided by an average cell voltage.

3. The battery system of claim 1, the controller of the BMS is configured to:
determine a physical location of the fault based at least on voltage measurements of each cell voltage in a series string and the battery pack positive and/or negative voltage.

4. The battery system of claim 1, wherein the battery pack positive voltage is a measurement of a positive-most portion of a series connection of the plurality of battery cells with respect to the chassis ground.

5. The battery system of claim 1, wherein the battery negative voltage is a measurement of a negative-most portion of a series connection of the plurality of battery cells with respect to the chassis ground.

6. The battery system of claim 1, wherein the determining the electrical location of the fault in the plurality of HV battery packs is based at least on cell voltages.

7. The battery system of claim 1, the controller of the BMS is configured to:
determine, using at least measured values from or of the HV battery packs, an exact physical location of the isolation breakdown, the measured values comprising isolation resistance, the battery pack positive voltage, the battery pack negative voltage, and cell voltages.

8. The battery system of claim 7, wherein the battery pack positive voltage is a measurement of a most positive portion of a series connection of the plurality of battery cells with respect to a chassis ground; and wherein the battery pack negative voltage is a measurement of a most negative portion of a series connection of the plurality of battery cells with respect to a chassis ground, wherein a sum of a magnitude of the battery pack positive voltage and the battery pack negative voltage values equals a total pack voltage.

9. The battery system of claim 7, wherein the isolation resistance is calculated by connecting a known resistance between either the battery pack positive voltage and a chassis ground or the battery pack negative voltage and the chassis ground and calculating a change in voltage measurement.

10. A method of determining a location of a fault in a plurality of HV battery packs of a battery system of an electric vehicle, comprising:
identifying an isolation breakdown based at least on whether a low resistance connection exists between a portion of a series connection of a plurality of battery cells of the plurality of HV battery packs and a chassis ground of the electric vehicle; and
determining an electrical location of a fault in the plurality of HV battery packs based at least on a battery pack positive voltage and a battery pack negative voltage.

11. The method of claim 10, further comprising:
determining a physical location of the fault based at least on a number of the plurality of battery cells less the battery pack positive voltage divided by an average cell voltage.

12. The method of claim 10, further comprising:
determining a physical location of the fault based at least on voltage measurements of each cell voltage in a series string and the battery pack positive and/or negative voltage.

13. The method of claim 10, wherein the determining the electrical location of the fault in the plurality of HV battery packs is based at least on cell voltages.

14. The method of claim 10, further comprising:
determining, using at least measured values from or of the HV battery packs, an exact physical location of the isolation breakdown, the measured values comprising isolation resistance, the battery pack positive voltage, the battery pack negative voltage, and cell voltages.

15. The method of claim 10, further comprising:
determining a total pack voltage by summing a magnitude of the battery pack positive voltage and the battery pack negative voltage.

16. The method of claim 10, further comprising:
calculating the isolation resistance by:
connecting a known resistance between either the battery pack positive voltage and a chassis ground or the battery pack negative voltage and the chassis ground; and
calculating a change in voltage measurement.

17. An electric vehicle, comprising:
one or more electric motors configured to propel the electric vehicle; and
a battery system configured to provide power to the one or more electric motors, wherein the battery system comprises a battery controller and a plurality of battery modules electrically connected together, each battery module of the plurality of battery modules including a plurality of battery cells positioned within a volume of the battery module, the battery controller being configured to:
identify an isolation breakdown based at least on whether a low resistance connection exists between a portion of a series connection of the plurality of battery cells and a chassis ground of the electric vehicle; and
determine an electrical location of a fault in the plurality of HV battery packs based at least on a battery pack positive voltage and a battery pack negative voltage.

18. The electric vehicle of claim 17, the battery controller configured to:
determine a physical location of the fault based at least on a number of the plurality of battery cells less the battery pack positive voltage divided by an average cell voltage.

19. The electric vehicle of claim 17, the battery controller configured to:
determine a physical location of the fault based at least on voltage measurements of each cell voltage in a series string and the battery pack positive and/or negative voltage.

20. The electric vehicle of claim 17, wherein the battery pack positive voltage is a measurement of a positive-most portion of a series connection of the plurality of battery cells with respect to the chassis ground.
